(19) United States
(12) Patent Application Publication
(10) Pub. No.: US 2026/0186030 A1
(43) Pub. Date: Jul. 2, 2026

(54) Server Information Handling System Voltage Measurement Sense Signal System

(71) Applicant: Dell Products L.P., Round Rock, TX (US)

(72) Inventors: Charles Ziegler, East Providence, RI (US); Jason Pritchard, Hopkinton, MA (US)

(21) Appl. No.: 19/003,759

(22) Filed: Dec. 27, 2024

(51) Int. Cl. G01R 19/00

(52) U.S. Cl. CPC G01R 19/0084

(57) ABSTRACT

A voltage measurement sense signal system for an information handling system. The voltage measurement sense signal system includes a power source, the power source having an associated voltage differential, the power source having a remote sense signal; and, a voltage measurement sense signal circuit, the voltage measurement sense signal circuit being coupled to the remote sense signal and another remote sense signal, the voltage measurement sense signal circuit combining remote sense signal and another remote sense signal before traversing a combined remote sense signal to a subsequent recipient.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server type information handling system with a voltage measurement sense signal system.

In one embodiment, the invention relates to a voltage measurement sense signal system for an information handling system comprising a power source, the power source having an associated voltage differential, the power source having a remote sense signal; and, a voltage measurement sense signal circuit, the voltage measurement sense signal circuit being coupled to the remote sense signal and another remote sense signal, the voltage measurement sense signal circuit combining remote sense signal and another remote sense signal before traversing a combined remote sense signal to a subsequent recipient.

In another embodiment, the invention relates to a power system for an information handling system comprising: a component, the component having an associated voltage differential, the component having a component remote sense signal coupled across the associated voltage differential; a power source, the power source having an associated voltage differential, the power source having a remote sense signal; and, a voltage measurement sense signal circuit, the voltage measurement sense signal circuit being coupled to the remote sense signal and another remote sense signal, the voltage measurement sense signal circuit combining remote sense signal and another remote sense signal before traversing a combined remote sense signal to a subsequent recipient.

In another embodiment, the invention relates to a system comprising: a chassis; a plurality of components contained within the chassis; and, a power system providing power to the plurality of components, the power system comprising a power source, the power source having an associated voltage differential, the power source having a remote sense signal; and, a voltage measurement sense signal circuit, the voltage measurement sense signal circuit being coupled to the remote sense signal and another remote sense signal, the voltage measurement sense signal circuit combining remote sense signal and another remote sense signal before traversing a combined remote sense signal to a subsequent recipient.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIGS. 1A and 1B, generally referred to as FIG. 1, labeled Prior Art, show generalized schematic views of known power systems.

FIG. 2 shows a general illustration of components of an information handling system as implemented in the system and method of the present invention.

FIG. 3 shows a perspective view of a portion of a data center within an IT environment.

FIG. 4 shows a generalized perspective view of an example server type information handling system.

FIG. 5 shows a generalized schematic view of a power system having a voltage measurement sense signal system.

FIG. 6 shows a generalized schematic view of a power environment which includes a power system having a voltage measurement sense signal system.

### DETAILED DESCRIPTION

Various aspects of the present disclosure include an appreciation that server type information handling system structural designs are becoming increasingly large as a function of growing component size and increasing heat loads within the system. Various aspects of the present disclosure include an appreciation that it is known to provide information handling systems with a plurality of components. Various aspects of the present disclosure include an appreciation that graphics processing unit (GPU) modules (often referred to as accelerator add in cards (AICs) and drive modules are examples of components that are often included within an information handling system. Various aspects of the present disclosure include an appreciation that it may be desirable to provide an information handling system with an array of components. Various aspects of the present disclosure include an appreciation that it may be desirable to install an array of GPU modules within an information handling system.

Various aspects of the present disclosure include an appreciation that GPU modules are often configured to conform to form factor standards. Various aspects of the present disclosure include an appreciation that the card electromechanical (CEM) form factor standard is one such form factor standard. Various aspects of the disclosure include an appreciation that it is known to provide information handling systems with baseboard systems such as peripheral component interconnect express (PCIe) type baseboard systems.

Various aspects of the present disclosure include an appreciation that powering an array of components can often require high power. Various aspects of the present disclosure include an appreciation that providing this high power can often require high powered power systems often having a plurality of power supply units. These issues are especially present in systems which are designed with a plurality of components such as a plurality of GPUs. These issues are also especially present in systems which are designed with an array of AICs, such as in systems which are designed to support artificial intelligence (AI) workloads.

Various aspects of the present disclosure include an appreciation that remote sense (RMTS) signals are often used by power systems to identify any voltage drop that may occur across a power distribution network of the power system. Various aspects of the present disclosure include an appreciation that such a voltage drop can be due to intrinsic losses such as printed circuit board or cable resistances.

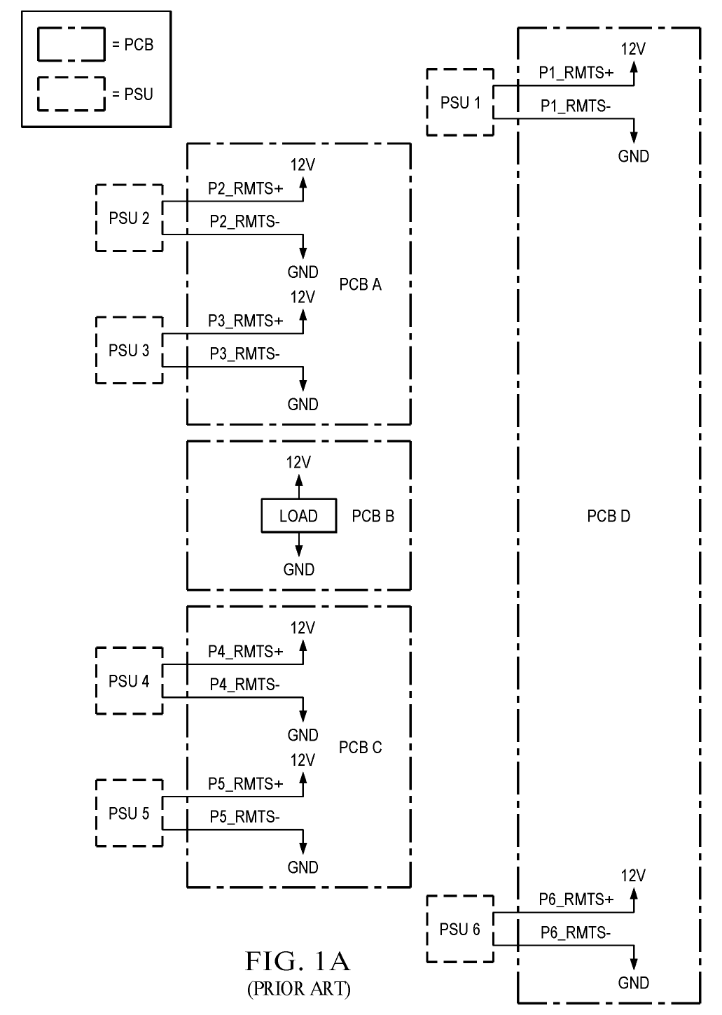

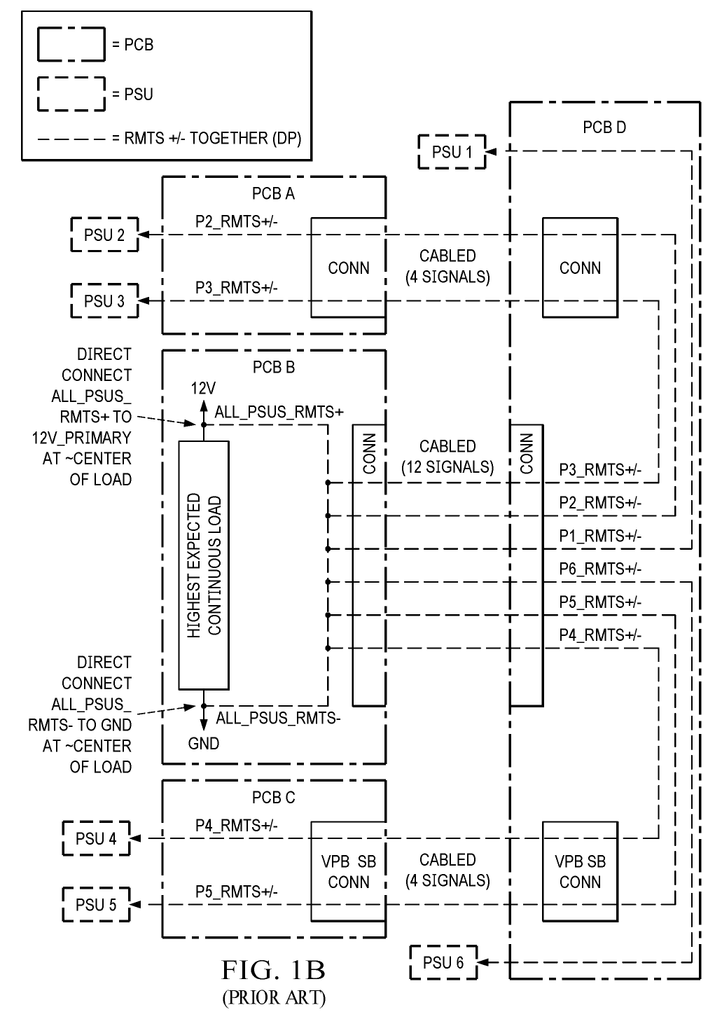

Various aspects of the present disclosure include an appreciation that many known server type information handling systems are designed with proximally co-located power supply units and power loads. Various aspects of the present disclosure include an appreciation that because of this proximate co-location, the sensing signals may be configured as local sensing signals, Various aspects of the present disclosure include an appreciation that because of this proximate co-location, remote sensing signals are often not needed or used in these designs. For example, FIG. 1A, labeled Prior Art, shows a generalized schematic view of a multi power supply power system proximally co-located power supply units. With this example, voltage at the load is not monitored and there is no voltage compensation for any voltage losses at the load. Various aspects of the present disclosure include an appreciation that with server type information handling systems having arrays of components, proximate co-location of power supply units and loads is often not possible.

Various aspects of the present disclosure include an appreciation that with server type information handling systems having arrays of components, the power requirements of the array of components often require power systems having a plurality of power supply units and associated circuit boards and cables to distribute power to the plurality of components. Various aspects of the present disclosure include an appreciation that the plurality of power supply units and associated circuit boards and cables can result in voltage degradation. Various aspects of the present disclosure include an appreciation that coupling remote sense signals to the load can help identify the potential voltage degradation.

Various aspects of the present disclosure include an appreciation that configuring the multi power supply power systems with remote sense signals can result in multiple signal paths which often must traverse many cables and connectors. Various aspects of the present disclosure include an appreciation that configuring the multi power supply power systems with remote sense signals can result in multiple signal paths can add cost to the system, can negatively impact system density, or a combination thereof. Various aspects of the present disclosure include an appreciation that known power system remote sense signals are not designed to monitor multiple load points, which can present issues in systems with multiple high current demanding loads in various locations across the system. For example, FIG. 1B, labeled Prior Art, shows a generalized schematic view of a multi power supply power system having a plurality of remote sense signals. This example shows a remote sense configuration which monitors the voltage at a load via individually traversing differential pairs where the load is the highest expected continuous load.

Various aspects of the present disclosure include an appreciation that it would be desirable to provide a power sensing solution which reduces the number of sense signal paths, the length of the sense signal paths, or a combination thereof. Various aspects of the present disclosure include an appreciation that it would be desirable to provide a power sensing solution which mitigates the number of connector pins and cable conductors needed in a system to maximize density and decrease cost. Various aspects of the present disclosure include an appreciation that it would be desirable to provide stable voltage regulation across multiple loads at various locations within the system.

A system and method are disclosed for providing a power system of a server type information handling system with a voltage measurement sense signal system. In certain embodiments, the voltage measurement sense signal system includes a voltage measurement sense signal circuit. In certain embodiments, the voltage measurement sense signal circuit combines a plurality of remote sense signal paths before traversing the sense signal paths to a subsequent recipient such as subsequent circuit boards.

In certain embodiments, the combination of the plurality of remote sense signal paths is achieved by including tactically placed low pass filters. As used herein, a low pass filter refers to one or more electrical components that are configured as a signal filter that passes signals with a frequency lower than a selected cutoff frequency and attenuates signals with frequencies higher than the cutoff frequency. It will be appreciated that the configuration of the one or more electrical components is a matter of design choice. As used herein, a tactically placed low pass filter refers to a low pass filter which is located physically proximate to a component, such as a power supply unit, which is interacting with a particular remote sense signal path. In certain embodiments, physically proximate low pass filters are located within 5 cm+/- 25% of the component. In certain embodiments, physically proximate low pass filters are located between the component, such as a power supply, which is interacting with the particular remote sense signal and a remote sense signal connector associated with the component. In certain embodiments, the low pass filters mitigate noise propagation between power supply units.

In certain embodiments, the combination of the plurality of sense signal paths mitigates the number of connector pins and cable conductors needed to perform a voltage sense operation such as a remote sense operation. As used herein, a sense operation broadly refers to a technique used in power systems to produce a correct voltage for a load. As used herein, a remote sense operation broadly refers to a technique used in power systems to identify a voltage at a load where the voltage at the load may have a voltage drop due to resistance between a power source of the power system and a load of the power system. In certain embodiments, the remote sense operation further includes controlling the power source to contract the voltage drop. In certain embodiments, remote sense signal paths associated with the load are used in performance of the remote sense operation. In certain embodiments, the remote sense signal paths include sense leads coupled to power terminals of the load to measure the voltage at the power terminals.

In certain embodiments, the voltage measurement sense signal circuit includes an averaging stage. In certain embodiments, the averaging stage averages sense results from a plurality of sense lines. In certain embodiments, the averaging the sense results enables determination of an average voltage across a plurality of loads. In certain embodiments, the averaging stage facilitates stable voltage regulation across multiple loads at various locations.

In certain embodiments, the averaging stage averages losses across a plurality of power paths to multiple loads. By so averaging the losses, the voltage measurement sense signal circuit can provide an average voltage compensation across the loads. In certain embodiments, the average voltage compensation mitigates a potential of a load receiving too high of a voltage or too low of a voltage. For example, without the average voltage compensation a load that is proximate conductively to the power supplies may receive too high of a voltage if the sense lines only take into account a load that is further away conductively from the supplies.

Such a voltage measurement sense signal system advantageously provides a power sensing solution which mitigates the number of connector pins and cable conductors needed in a system. Such a voltage measurement sense signal system advantageously maximizes density and decreases cost. Such a voltage measurement sense signal system advantageously provides stable voltage regulation across multiple loads at various locations within the system.

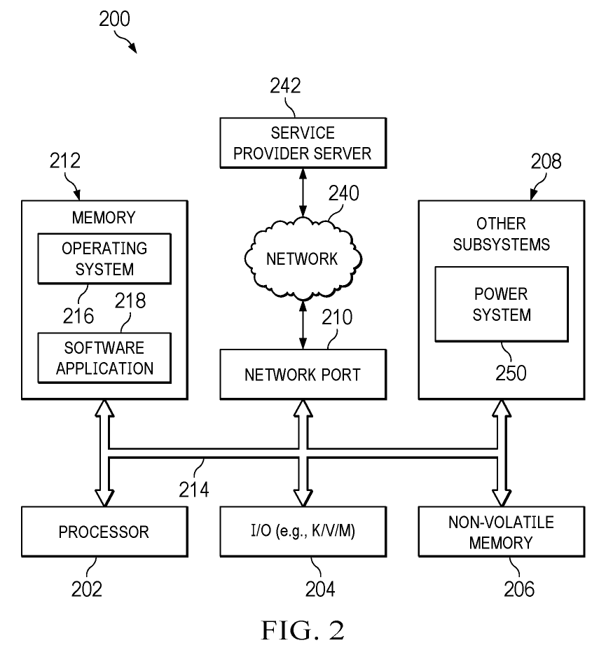

FIG. 2 shows a generalized illustration of an information handling system 200 that can be used to implement the system and method of the present invention. The information handling system 200 includes a processor (e.g., central processor unit or “CPU”) 202, input/output (I/O) devices 204, such as a display, a keyboard, a mouse, and associated controllers, a hard drive or disk storage 206, and various other subsystems 208. In various embodiments, the information handling system 200 also includes network port 210 operable to connect to a network 240, which is likewise accessible by a service provider server 242. In various embodiments, one or both the other subsystems 208 or the network port 210 include a power system 250. The information handling system 200 likewise includes system memory 212, which is interconnected to the foregoing via one or more buses 214. System memory 212 further comprises operating system (OS) 216. In certain embodiments, the information handling system 200 is one of a plurality of information handling systems within a data center. In certain embodiments, the information handling system 200 comprises a server type information handling system. In certain embodiments, the server type information handling system is configured to be mounted within a server rack. In certain embodiments, the other subsystem 208 includes one or more power supplies for supplying power to the other components of the information handling system 200.

In certain embodiments, the information handling system 200 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the power system 250 is part of a power system environment which includes a includes a power system and a plurality of components coupled to the power system. In certain embodiments, the plurality of components are arranged as an array of components. In certain embodiments, the plurality of components includes a plurality of GPUs. In certain embodiments, the plurality of GPUs are designed to support artificial intelligence (AI) workloads.

In certain embodiments, the power system 250 includes a voltage measurement sense signal system. In certain embodiments, the voltage measurement sense signal system includes a voltage measurement sense signal circuit. In certain embodiments, the voltage measurement sense signal circuit combines a plurality of sense lines before traversing the sense signal paths to a subsequent recipient such as subsequent circuit boards.

In certain embodiments, the combination of the plurality of remote sense signal paths is achieved by including tactically placed low pass filters. In certain embodiments, the low pass filters mitigate noise propagation between power supply units. In certain embodiments, the combination of the plurality of sense signal paths mitigates the number of connector pins and cable conductors needed to perform a voltage sense operation such as a remote sense operation. As used herein, a sense operation broadly refers to a technique used in power systems to produce a correct voltage for a load. As used herein, a remote sense operation broadly refers to a technique used in power systems to identify a voltage at a load where the voltage at the load may have a voltage drop due to resistance between a power source of the power system and a load of the power system. In certain embodiments, the remote sense operation further includes controlling the power source to contract the voltage drop. In certain embodiments, remote sense signal paths associated with the load are used in performance of the remote sense operation. In certain embodiments, the remote sense signal paths include sense leads coupled to power terminals of the load to measure the voltage at the power terminals.

In certain embodiments, the voltage measurement sense signal circuit includes an averaging stage. In certain embodiments, the averaging stage averages sense results from a plurality of sense lines. In certain embodiments, the averaging the sense results enables determination of an average voltage across a plurality of loads. In certain embodiments, the averaging stage facilitates stable voltage regulation across multiple loads at various locations.

In certain embodiments, the averaging stage averages losses across a plurality of power paths to multiple loads. By so averaging the losses, the voltage measurement sense signal circuit can provide an average voltage compensation across the loads. In certain embodiments, the average voltage compensation mitigates a potential of a load receiving too high of a voltage or too low of a voltage. For example, without the average voltage compensation a load that is proximate conductively to the power supplies may receive too high of a voltage if the sense lines only take into account a load that is further away conductively from the supplies.

Such a voltage measurement sense signal system advantageously provides a power sensing solution which mitigates the number of connector pins and cable conductors needed in a system. Such a voltage measurement sense signal system advantageously maximizes density and decreases cost. Such a voltage measurement sense signal system advantageously provides stable voltage regulation across multiple loads at various locations within the system.

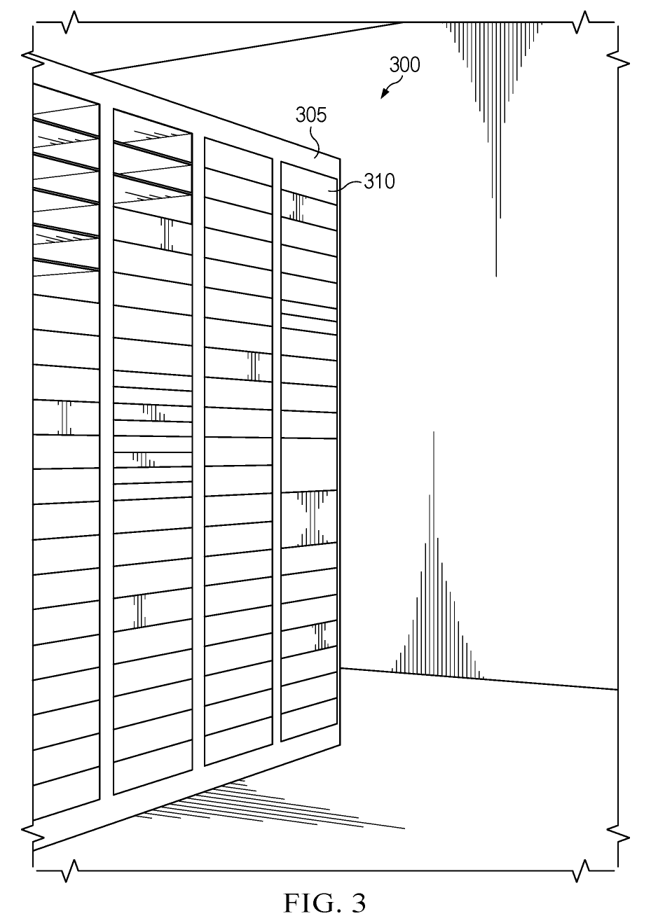

FIG. 3 shows a perspective view of a portion of an IT environment 300. The IT environment includes one or more racks 305 which include a plurality of information handling systems 200, often referred to as a server rack. In various embodiments, the IT environment 300 comprises a data center. As used herein, a data center refers to an IT environment which includes a plurality of networked information handling systems 200. In various embodiments, the information handling systems 200 of the data center include some or all of router type information handling systems, switch type information handling systems, firewall type information handling systems, storage system type information handling systems, server type information handling systems and application delivery controller type information handling systems. In certain environments, the information handling systems 200 are mounted within respective racks. As used herein, a rack refers to a physical structure that is designed to house the information handling systems 200, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 310. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/-20%) 1.75” high, a 2U rack unit is substantially (i.e., +/-20%) 3.5” high, and a 4U rack height is substantially (i.e., +/-20%) 7.0” high.

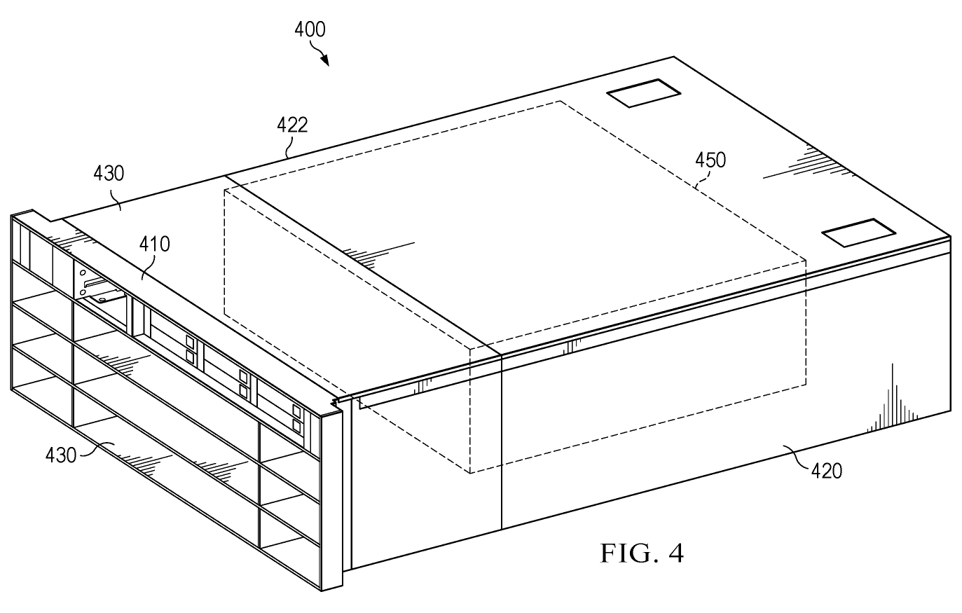

FIG. 4 shows a generalized perspective view of an example blade server type information handling system 400. In certain embodiments, the server type information handling system includes a front portion 410, which is accessible when the server type information handing system 400 is mounted on a server rack. In certain embodiments, the side portions 420, 422 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 400 may be accessed by removing a top panel 430 of the blade type information handing system 400. In certain embodiments, the server system 400 includes a power division and identification environment 450. In certain embodiments, the system environment 450 corresponds to power system 250.

In certain embodiments, the power system environment 450 includes a power system and a plurality of components coupled to the power system. In certain embodiments, the plurality of components are arranged as an array of components. In certain embodiments, the plurality of components includes a plurality of GPUs. In certain embodiments, the plurality of GPUs are designed to support artificial intelligence (AI) workloads.

In certain embodiments, the power system environment 450 includes a voltage measurement sense signal system. In certain embodiments, the voltage measurement sense signal system includes a voltage measurement sense signal circuit. In certain embodiments, the voltage measurement sense signal circuit combines a plurality of sense lines before traversing the sense signal paths to a subsequent recipient such as subsequent circuit boards.

In certain embodiments, the combination of the plurality of remote sense signal paths is achieved by including tactically placed low pass filters. In certain embodiments, the low pass filters mitigate noise propagation between power supply units. In certain embodiments, the combination of the plurality of sense signal paths mitigates the number of connector pins and cable conductors needed to perform a voltage sense operation such as a remote sense operation. In certain embodiments, remote sense signal paths associated with the load are used in performance of the remote sense operation. In certain embodiments, the remote sense signal paths include sense leads coupled to power terminals of the load to measure the voltage at the power terminals.

In certain embodiments, the voltage measurement sense signal circuit includes an averaging stage. In certain embodiments, the averaging stage averages sense results from a plurality of sense lines. In certain embodiments, the averaging the sense results enables determination of an average voltage across a plurality of loads. In certain embodiments, the averaging stage facilitates stable voltage regulation across multiple loads at various locations.

In certain embodiments, the averaging stage averages losses across a plurality of power paths to multiple loads. By so averaging the losses, the voltage measurement sense signal circuit can provide an average voltage compensation across the loads. In certain embodiments, the average voltage compensation mitigates a potential of a load receiving too high of a voltage or too low of a voltage. For example, without the average voltage compensation a load that is proximate conductively to the power supplies may receive too high of a voltage if the sense lines only take into account a load that is further away conductively from the supplies.

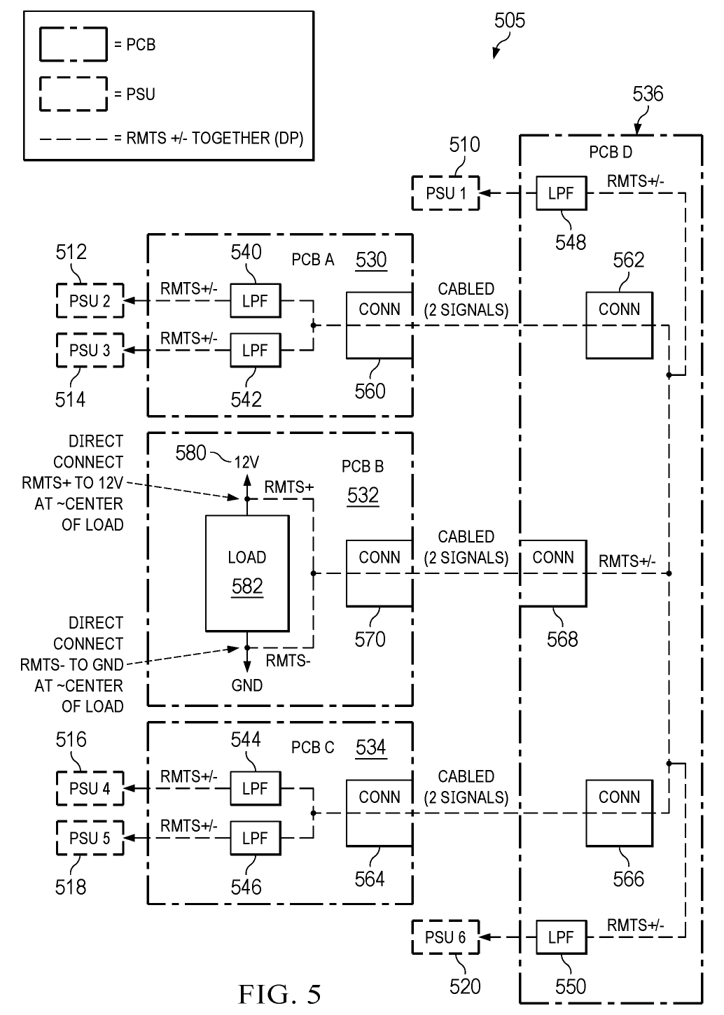

FIG. 5 shows a generalized schematic view of a power system 500 having a voltage measurement sense signal system. In certain embodiments, the power system 500 corresponds to power system 250.

In certain embodiments, the power system 500 includes a plurality of power supply units, a voltage measurement sense signal system 505, or a combination thereof. In certain embodiments, the plurality of power supply units include one or more of power supply PSU1 510, power supply unit PSU2 512, power supply unit PSU3 514, power supply PSU4 516, power supply unit PSU5 518, power supply unit PSU6 520, etc. In certain embodiments, the voltage measure sense signal system 505 includes a plurality of printed circuit boards. In certain embodiments, the plurality of printed circuit boards include one or more of printed circuit board PCB A 530, printed circuit board PCB B 532, printed circuit board PCB C 534, printed circuit board PCB D 536, etc. In certain embodiments, the one or more of printed circuit board PCB A 530, printed circuit board PCB B 532, printed circuit board PCB C 534, printed circuit board PCB D 536 correspond to a system circuit board. In certain embodiments, printed circuit board PCB D 536 corresponds to a system circuit board. In certain embodiments, the system circuit board includes one or more of a motherboard, a planar circuit board, a high performance module circuit board, and a baseboard circuit board.

In certain embodiments, the voltage measurement sense signal system 505 includes a voltage measurement sense signal circuit. In certain embodiments, the voltage measure sense signal circuit includes a plurality of sense signal circuit components. In certain embodiments, the plurality sense signal circuit components include a plurality of sense signal paths, a plurality of sense signal connectors, a plurality of low pass filters, a load voltage source, or a combination thereof. In certain embodiments, the plurality of components of the voltage measurement sense signal circuit are distributed across one or more of the plurality of printed circuit boards (PCB A, PCB B, PCB C, PCB D). In certain embodiments, the plurality of sense signal paths, the plurality of sense signal connectors, the plurality of low pass filters, the load voltage source, or a combination thereof, are distributed across one or more of the plurality of printed circuit boards (PCB A, PCB B, PCB C, PCB D).

In certain embodiments, the voltage measurement sense signal circuit combines a plurality of the remote sense signal paths to provide a combined remote sense signal path before traversing the combined sense signal path to a subsequent recipient such as subsequent circuit boards such as one or more of the plurality of printed circuit boards (PCB A, PCB B, PCB C, PCB D). In certain embodiments, sense signal paths are combined on printed circuit board PCB A 530 before the sense signal paths are traversed to the subsequent circuit board PCB D 536. In certain embodiments, sense signal paths are combined on printed circuit board PCB B 532 before the sense signal paths are traversed to the subsequent circuit board PCB D 536. In certain embodiments, sense signal paths are combined on printed circuit board PCB D 536 before the sense signal paths are traversed to the subsequent circuit boards PCB B 532.

In certain embodiments, the combination of the plurality of remote sense signal paths is achieved by including tactically placed low pass filters (LPFs). In certain embodiments, the low pass filters mitigate noise propagation between power supply units. In certain embodiments, the combination of the plurality of sense signal paths mitigates the number of connector pins and cable conductors needed to perform a voltage sense operation such as a remote sense operation. In certain embodiments, remote sense signal paths associated with the load are used in performance of the remote sense operation. In certain embodiments, the remote sense signal paths include sense leads coupled to power terminals of the load to measure the voltage at the power terminals.

In certain embodiments, printed circuit board PCB A 530 includes low pass filters 540, 542, printed circuit board PCB C 534 includes low pass filters 544, 546, and printed circuit board PCB D 536 includes low pass filters 548, 550. In certain embodiments, the low pass filter 540 is coupled to power supply unit PSU2 512 via a differential pair remote sense signal path (RMTS +/-). In certain embodiments, the low pass filter 542 is coupled to power supply unit PSU3 514 via a differential pair sense signal path (RMTS +/-). In certain embodiments, the low pass filter 544 is coupled to power supply unit PSU4 516 via a differential pair remote sense signal path (RMTS +/-). In certain embodiments, the low pass filter 546 is coupled to power supply unit PSU5 518 via a differential pair sense signal path (RMTS +/-). In certain embodiments, the low pass filter 548 is coupled to power supply unit PSU1 510 via a differential pair remote sense signal path (RMTS +/-). In certain embodiments, the low pass filter 550 is coupled to power supply unit PSU6 520 via a differential pair sense signal path (RMTS +/-).

In certain embodiments, the sense signal path coupled from power supply unit PSU2 512 to low pass filter 540 and the sense signal path coupled from power supply unit PS3 514 to low pass filter 542 are combined and provided to sense signal connector 560 which is in turn coupled to connector 562 via a cable. In certain embodiments, the sense signal path coupled from power supply unit PSU4 516 to low pass filter 544 and the sense signal path coupled from power supply unit PS5 518 to low pass filter 546 are combined and provided to sense signal connector 564 which is in turn coupled to connector 566 via a cable. In certain embodiments, the sense signal path coupled from power supply unit PSU1 510 to low pass filter 548 and the sense signal path coupled from power supply unit PS6 520 to low pass filter 550 are combined and provided to sense signal connector 568. The sense signal paths from connector 562 and connector 566 are combined and are also provided to connector 568. The combined sense signal path from connector 568 is then provided to connector 570 via a cable. Connector 570 receives a remote sense positive signal and a remote sense negative signal from a direction connection of a power source 580 to a load 582. In certain embodiments, the power source 580 is a 12V power source. In certain embodiments, the load is coupled between the 12V power source and ground. In certain embodiments, the load is physically located at a center of a plurality of loads. In certain embodiments, the plurality of loads correspond to a plurality of components. In certain embodiments, the plurality of components correspond to an array of GPU modules.

In certain embodiments, the combination of the plurality of sense signal paths mitigates the number of connectors, connector pins and cable conductors needed to perform a voltage sense operation. In certain embodiments, the combination of the plurality of sense signal paths reduces the total number of sense signal paths by a fourteen signal paths.

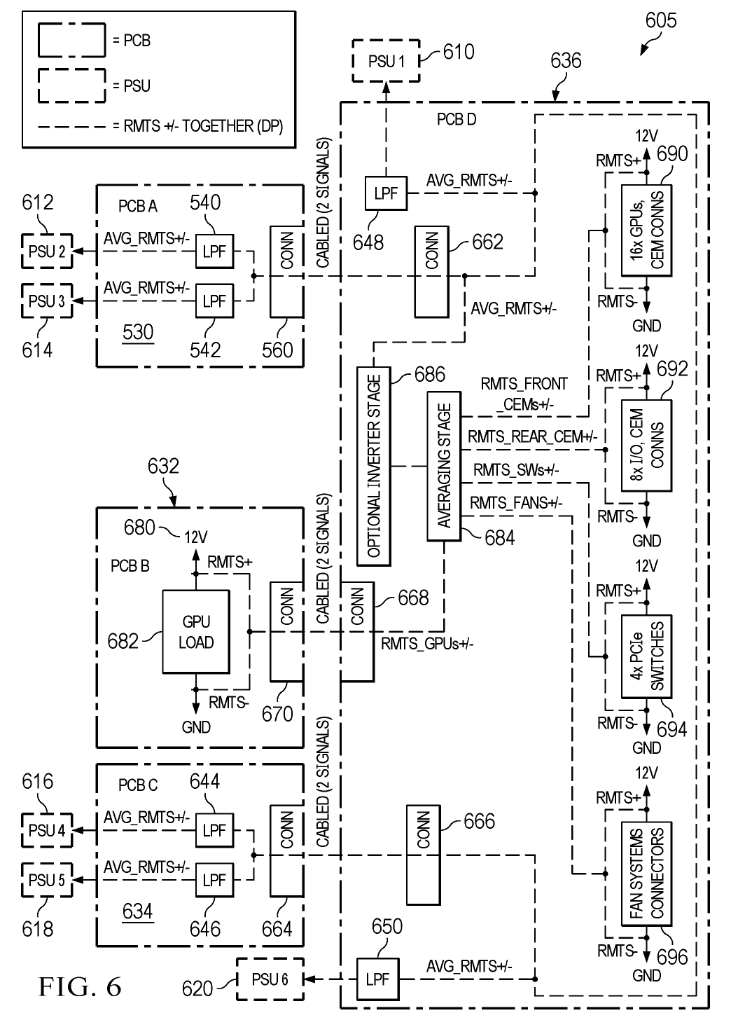

FIG. 6 shows a generalized schematic view of a power environment which includes a power system 600 having a voltage measurement sense signal system. In certain embodiments, the power system 600 corresponds to power system 250.

In certain embodiments, the power system 600 includes a plurality of power supply units, a voltage measurement sense signal system 605, or a combination thereof. In certain embodiments, the plurality of power supply units include one or more of power supply PSU1 610, power supply unit PSU2 612, power supply unit PSU3 614, power supply PSU4 616, power supply unit PSU5 618, power supply unit PSU6 620, etc. In certain embodiments, the voltage measure sense signal system 605 includes a plurality of printed circuit boards. In certain embodiments, the plurality of printed circuit boards include one or more of printed circuit board PCB A 630, printed circuit board PCB B 632, printed circuit board PCB C 634, printed circuit board PCB D 636, etc. In certain embodiments, the one or more of printed circuit board PCB A 630, printed circuit board PCB B 632, printed circuit board PCB C 634, printed circuit board PCB D 636 correspond to a system circuit board. In certain embodiments, printed circuit board PCB D 636 corresponds to a system circuit board. In certain embodiments, the system circuit board includes one or more of a motherboard, a planar circuit board, a high performance module circuit board, and a baseboard circuit board.

In certain embodiments, the voltage measurement sense signal system 605 includes a voltage measurement sense signal circuit. In certain embodiments, the voltage measure sense signal circuit includes a plurality of sense signal circuit components. In certain embodiments, the plurality sense signal circuit components include a plurality of sense signal paths, a plurality of sense signal connectors, a plurality of low pass filters, a load voltage source, an averaging circuit, a plurality of component connectors, or a combination thereof. In certain embodiments, the plurality of components of the voltage measurement sense signal circuit are distributed across one or more of the plurality of printed circuit boards (PCB A, PCB B, PCB C, PCB D). In certain embodiments, the plurality of sense signal paths, the plurality of sense signal connectors, the plurality of low pass filters, the load voltage source, or a combination thereof, are distributed across one or more of the plurality of printed circuit boards (PCB A, PCB B, PCB C, PCB D). In certain embodiments, the plurality of component connectors include one or more of GPU module CEM connectors, I/O CEM connectors, PCIe switch connectors, fan system connectors, etc.

In certain embodiments, the voltage measurement sense signal circuit combines a plurality of the remote sense signal paths to provide a combined remote sense signal path before traversing the combined sense signal path to a subsequent recipient such as subsequent circuit boards such as one or more of the plurality of printed circuit boards (PCB A, PCB B, PCB C, PCB D). In certain embodiments, sense signal paths are combined on printed circuit board PCB A 630 before the sense signal paths are traversed to the subsequent circuit board PCB D 636. In certain embodiments, sense signal paths are combined on printed circuit board PCB B 632 before the sense signal paths are traversed to the subsequent circuit board PCB D 636. In certain embodiments, sense signal paths are combined on printed circuit board PCB D 636 before the sense signal paths are traversed to the subsequent circuit boards PCB B 632.

In certain embodiments, the combination of the plurality of remote sense signal paths is achieved by including tactically placed low pass filters. In certain embodiments, the low pass filters mitigate noise propagation between power supply units. In certain embodiments, the combination of the plurality of sense signal paths mitigates the number of connector pins and cable conductors needed to perform a voltage sense operation such as a remote sense operation. In certain embodiments, remote sense signal paths associated with the load are used in performance of the remote sense operation. In certain embodiments, the remote sense signal paths include sense leads coupled to power terminals of the load to measure the voltage at the power terminals.

In certain embodiments, printed circuit board PCB A 630 includes low pass filters 640, 642, printed circuit board PCB C 634 includes low pass filters 644, 646, and printed circuit board PCB D 636 includes low pass filters 648, 650. In certain embodiments, the low pass filter 640 is coupled to power supply unit PSU2 612 via a differential pair remote sense signal path (RMTS +/-). In certain embodiments, the low pass filter 642 is coupled to power supply unit PSU3 614 via a differential pair sense signal path (RMTS +/-). In certain embodiments, the low pass filter 644 is coupled to power supply unit PSU4 616 via a differential pair remote sense signal path (RMTS +/-). In certain embodiments, the low pass filter 646 is coupled to power supply unit PSU5 618 via a differential pair sense signal path (RMTS +/-). In certain embodiments, the low pass filter 648 is coupled to power supply unit PSU1 610 via a differential pair remote sense signal path (RMTS +/-). In certain embodiments, the low pass filter 650 is coupled to power supply unit PSU6 620 via a differential pair sense signal path (RMTS +/-).

In certain embodiments, the sense signal path coupled from power supply unit PSU2 612 to low pass filter 640 and the sense signal path coupled from power supply unit PS3 614 to low pass filter 642 are combined and provided to sense signal connector 660 which is in turn coupled to connector 662 via a cable. In certain embodiments, the sense signal path coupled from power supply unit PSU4 616 to low pass filter 644 and the sense signal path coupled from power supply unit PS5 618 to low pass filter 646 are combined and provided to sense signal connector 664 which is in turn coupled to connector 666 via a cable. In certain embodiments, the sense signal path coupled from power supply unit PSU1 610 to low pass filter 648 and the sense signal path coupled from power supply unit PS6 620 to low pass filter 650 are combined and provided to sense signal connector 668. The sense signal paths from connector 662 and connector 666 are combined and are also provided to connector 668. The combined sense signal path from connector 668 is then provided to connector 670 via a cable. Connector 670 is receives a remote sense positive signal and a remote sense negative signal from a direction connection of a power source 680 to a load 682. In certain embodiments, the power source 680 is a 12V power source. In certain embodiments, the load is coupled between the 12V power source and ground. In certain embodiments, the load is physically located at a center of a plurality of loads. In certain embodiments, the plurality of loads correspond to a plurality of components. In certain embodiments, the plurality of components correspond to an array of GPU modules.

In certain embodiments, the combination of the plurality of sense signal paths mitigates the number of connectors, connector pins and cable conductors needed to perform a voltage sense operation.

In certain embodiments, the voltage measurement sense signal circuit includes an averaging stage 684, an inverter stage 686, or a combination thereof. In certain embodiments, the averaging stage 684, the inverter stage 686, or a combination thereof, are included on printed circuit board PCB D 636. In certain embodiments, the averaging stage 636 averages sense results from a plurality of remote sense signal paths. In certain embodiments, the plurality of remote sense signal paths includes remote sense signal paths coupled to a plurality of sets of component connectors. In certain embodiments, the plurality of sets of component connectors include one or more of a set of GPU module CEM connectors 690, as set of I/O CEM connectors 692, a set of PCIe switch connectors 694, a set of fan system connectors 696, or a combination thereof. In certain embodiments, each of the sets of component connectors are connected to respective sets of components. In certain embodiments, the remote sense signal paths coupled to the plurality of sets of component connectors provide remote sense voltage information associated with the respective sets of components. In certain embodiments, the respective sets of components have associated power loads and the remote sense voltage information is associated with the associated loads. In certain embodiments, the averaging the sense results enables determination of an average power load across the plurality of sets of components. In certain embodiments, the plurality of sets of components are physically located in different locations within the information handling system. In certain embodiments, the averaging stage 684 facilitates stable voltage regulation across the different locations of the plurality of loads generated by the sets of components.

In certain embodiments, the averaging stage 684 averages losses across a plurality of power paths to multiple loads. By so averaging the losses, the voltage measurement sense signal circuit can provide an average voltage compensation across the loads. In certain embodiments, the average voltage compensation mitigates a potential of a load receiving too high of a voltage or too low of a voltage. For example, without the average voltage compensation a load that is proximate conductively to the power supplies may receive too high of a voltage if the sense lines only take into account a load that is further away conductively from the supplies.

In certain embodiments, the inverter stage 686 is optional. In certain embodiments, the inverter stage compensates for polarity differences between various remote sensing signals.

Other embodiments are within the following claims. For example, a single power division and identification circuit could be associated with more than two component circuits by adding additional component detection circuit along with additional associated signal paths.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A voltage measurement sense signal system for use with an information handling system, comprising:
a power source, the power source having an associated voltage differential, the power source having a remote sense signal; and,
a voltage measurement sense signal circuit, the voltage measurement sense signal circuit being coupled to the remote sense signal and another remote sense signal, the voltage measurement sense signal circuit combining remote sense signal and another remote sense signal before traversing a combined remote sense signal to a subsequent recipient.

2. The voltage measurement sense signal system of claim 1, wherein:
the voltage measurement sense signal circuit includes a low pass filter and another low pass filter, the low pass filter being associated with the remote sense signal, the another low pass filter being associated with the another remote sense signal.

3. The voltage measurement sense signal system of claim 2, wherein:
the low pass filter and the another low pass filter are each tactically placed low pass filters.

4. The voltage measurement sense signal system of claim 2, wherein:
the low pass filter is located between a remote sense signal connector and the power source; and,
the another low pass filter is located between the remote sense signal connector and another power source.

5. The voltage measurement sense signal system of claim 1, wherein:
the voltage measurement sense signal circuit includes an averaging stage, the averaging stage averages sense results from a plurality of remote sense signal paths.

6. The voltage measurement sense signal system of claim 5, wherein:
the plurality of remote sense signal paths are coupled to a respective plurality of loads; and,
the averaging stage averages sense results associated with the respective plurality of loads.

7. A power system for an information handling system comprising:
a component, the component having an associated voltage differential, the component having a component remote sense signal coupled across the associated voltage differential;
a power source, the power source having an associated voltage differential, the power source having a remote sense signal; and,
a voltage measurement sense signal circuit, the voltage measurement sense signal circuit being coupled to the remote sense signal and another remote sense signal, the voltage measurement sense signal circuit combining remote sense signal and another remote sense signal before traversing a combined remote sense signal to the component.

8. The power system of claim 7, wherein:
the voltage measurement sense signal circuit includes a low pass filter and another low pass filter, the low pass filter being associated with the remote sense signal, the another low pass filter being associated with the another remote sense signal.

9. The power system of claim 8, wherein:
the low pass filter and the another low pass filter are each tactically placed low pass filters.

10. The power system of claim 8, wherein:
the low pass filter is located between a remote sense signal connector and the power source; and,
the another low pass filter is located between the remote sense signal connector and another power source.

11. The power system of claim 7, wherein:
the voltage measurement sense signal circuit includes an averaging stage, the averaging stage averages sense results from a plurality of remote sense signal paths.

12. The power system of claim 11, wherein:
the plurality of remote sense signal paths are coupled to a respective plurality of loads; and,
the averaging stage averages sense results associated with the respective plurality of loads.

13. A system comprising:
a chassis;
a plurality of components contained within the chassis; and,
a power system providing power to the plurality of components, the power system comprising
a power source, the power source having an associated voltage differential, the power source having a remote sense signal; and,
a voltage measurement sense signal circuit, the voltage measurement sense signal circuit being coupled to the remote sense signal and another remote sense signal, the voltage measurement sense signal circuit combining remote sense signal and another remote sense signal before traversing a combined remote sense signal to a subsequent recipient.

14. The system of claim 13, wherein:
the voltage measurement sense signal circuit includes a low pass filter and another low pass filter, the low pass filter being associated with the remote sense signal, the another low pass filter being associated with the another remote sense signal.

15. The system of claim 14, wherein:
the low pass filter and the another low pass filter are each tactically placed low pass filters.

16. The system of claim 14, wherein:
the low pass filter is located between a remote sense signal connector and the power source; and,
the another low pass filter is located between the remote sense signal connector and another power source.

17. The system of claim 13, wherein:
the voltage measurement sense signal circuit includes an averaging stage, the averaging stage averages sense results from a plurality of remote sense signal paths.

18. The system of claim 17, wherein:
the plurality of remote sense signal paths are coupled to a respective plurality of loads; and,
the averaging stage averages sense results associated with the respective plurality of loads.
